(19) United States
(12) Patent Application Publication
(10) Pub. No.: US 2003/0098684 A1
(43) Pub. Date: May 29, 2003

(54) Handler for tape carrier packages and method of traveling tape carrier package tape

(76) Inventor: Seiji Kuninobu, Tokyo (JP)

Correspondence Address: FLYNN THIEL BOUTELL & TANIS, P.C., 2026 RAMBLING ROAD, KALAMAZOO, MI, 49008-1699, US

(21) Appl. No.: 10/298,080

(22) Filed: Nov. 15, 2002

(30) Foreign Application Priority Data
Nov. 27, 2001 (JP) 2001-361158

(51) Int. Cl. G01R 1/00

(52) U.S. Cl. 324/158.1

(57) ABSTRACT

Stress is applied to a TCP tape during the travel of the TCP tape. The handler for TCPs for sequentially intermittently traveling a TCP tape comprises a plurality of continuously connected TCPs in a shape of a tape so as to move a measuring part provided in the midway of a traveling route of the TCP tape in a direction perpendicular to a surface of the TCP tape for allowing each semiconductor chip on each TCP to sequentially contact an opposed probe card to connect thereto, wherein flexure parts are formed on the TCP tape forward and backward of the measuring part in the traveling direction of the TCP tape, and the TCP tape is traveled by sprockets disposed forward and backward of the flexure parts in the traveling direction of the TCP tape.

### FIELD OF THE INVENTION

The invention relates to a handler for tape career packages (hereinafter referred to as TCPs) of a tape carrier package tape comprising a plurality of TCPs which are continuously connected to one another in the shape of a tape (hereafter referred to as a TCP tape) for sequentially connecting each semiconductor chip on each TCP to a probe card, and a method of traveling the TCP tape.

### BACKGROUND OF THE INVENTION

As is well known, a TCP is a package wherein an IC is mounted on a film using a TAB (tape automated bonding) technique, and in a carrier or transfer stage before the IC is mounted on a printed board, a plurality of TCPs are continuously connected to one another to form in a shape of a tape. FIG. 3 is a front view of each TCP formed in the shape of a tape, namely, TCP tape X. The TCP tape X comprises a plurality of TCPs which are continuously connected to one another, and has belt-like auxiliary transfer parts 10A at both sides thereof. Each TCP 10 has a plurality of test pads 10b at circumferential edge of each film substrate 10a and each IC chip 10c is disposed at the center thereof. Each test pad 10b and each pad formed on each IC chip 10c are mutually connected to each other by each lead line 10d which is formed by etching technique. The auxiliary transfer parts 10A are formed of a film like each film substrate 10a, they have sprocket holes 10e disposed at a predetermined interval for sequentially transferring the TCP tape X in a longitudinal direction thereof.

Such a conventional TCP tape X is sequentially intermittently transferred in a longitudinal direction by a handler for exclusive use of the TCPs, while each test pad 10b of each TCP 10 is brought into contact with and connected to a probe card connected to a semiconductor integrated circuit tester, whereby a predetermined functional test is effected. A technology relating to a handler for TCPs is disclosed, for example, in JP-A 2001-311761.

This handler for TAB has a configuration that a part of a traveling route of a TAB tape (TCP tape) is moved up and down by a pusher so that each IC chip on the TAB tape is brought into contact with and connected to a probe card while a prescribed tension is always applied to a supplying side tension guide and a receiving side tension guide respectively disposed forward and backward of the pusher in the traveling direction of the TCP tape X.

However, since the conventional handler for TCPs has a configuration that a predetermined tension is always applied to the supplying side tension guide and the receiving side tension guide, it is difficult to stably travel a TCP tape having a thin film substrate. In cases where such a thin TCP tape is traveled, stress caused by tension is applied to the TCP tape or to each TCP.

### SUMMARY OF THE INVENTION

The invention has been developed in view of the conventional handler for TCPs, and it is an object of the invention to reduce tension applied to a TCP tape during the travel thereof.

To achieve the above object, the invention adopts first means of a handler for TCPs comprising a plurality of continuously connected TCPs 10 in a shape of a tape so as to move a measuring part 4 provided in the midway of a traveling route of the TCP tape X in a direction perpendicular to a surface of the TCP tape X for allowing each semiconductor chip 10c on each TCP 10 to sequentially contact an opposed probe card 5 to connect thereto, wherein flexure parts T1, T2 are formed on the TCP tape X forward and backward of the measuring part 4 in the traveling direction of the TCP tape X, and the TCP tape X is traveled by sprockets 2B to 2E disposed forward and backward of the flexure parts T1, T2 in the traveling direction of the TCP tape X.

The handler for TCPs adopts second means wherein the handler for TCPs of the first means further comprises flexure formation members 7A, 7B provided at the front and the back of the measuring part 4, wherein said flexure formation members 7A, 7B are freely movable toward or away from the TCP tape X.

The handler for TCPs adopts third means wherein the measuring part 4 of the first means has an angular alignment mechanism for adjusting an angle of each TCP 10 relative to and within an opposed face of the probe card 5.

Meanwhile, the invention adopts first means of a method of traveling a TCP tape X comprising steps of sequentially intermittently traveling a TCP tape X comprising a plurality of continuously connected TCPs 10 in a shape of a tape so as to move a measuring part 4 provided in the midway of a traveling route of the TCP tape X in a direction perpendicular to a surface of the TCP tape X for allowing each semiconductor chip 10c on the TCPs 10 to sequentially contact an opposed a probe card 5 to connect thereto, said method further comprising, forming flexure parts T1, T2 on the TCP tape X forward and backward of the measuring part 4 in the traveling direction of the TCP tape X, and traveling the TCP tape X by sprockets 2B to 2E disposed forward and backward of the flexure parts T1, T2 in the traveling direction of the TCP tape X.

The method of traveling a TCP tape adopts second means wherein the flexure parts T1, T2 of the fourth means are formed by providing flexure formation members 7A, 7B at the front and the back of the measuring part 4, and the flexure formation members 7A, 7B are freely movable toward or away from the TCP tape X.

The method of traveling a TCP tape X adopts third means wherein the first means of the method of the first means further comprises adjusting an angle of each TCP 10 in the measuring part 4 relative to and within an opposed face of the probe card 5.

### BRIEF DESCRIPTION OF THE DRAWINGS

FIG. 1 is a front view showing a traveling system for a handler for TCPs according to an embodiment of the invention;

FIG. 2 is a view showing an explanation for forming flexure parts T1, T2 according to the embodiment of the invention; and

FIG. 3 is a view showing the configuration of a TCP tape X according to the invention and prior art.

### PREFERRED EMBODIMENT OF THE INVENTION

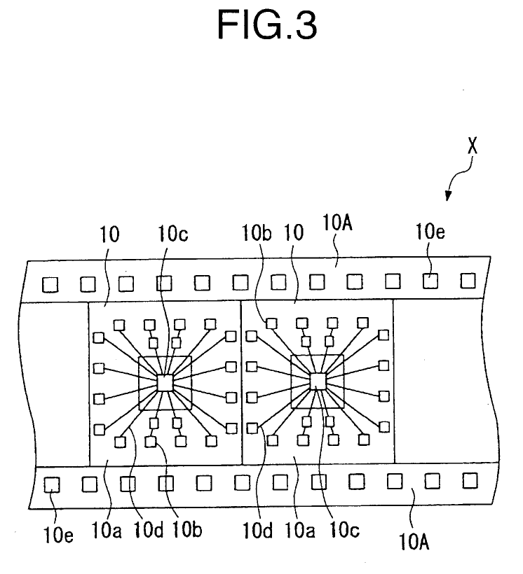

A handler for TCPs and a method of traveling a TCP tape according to a preferred embodiment of the invention is now described with reference to attached drawings. Since the TCP tape has been already described with reference to FIG. 3, and hence the explanation thereof is omitted in the following description.

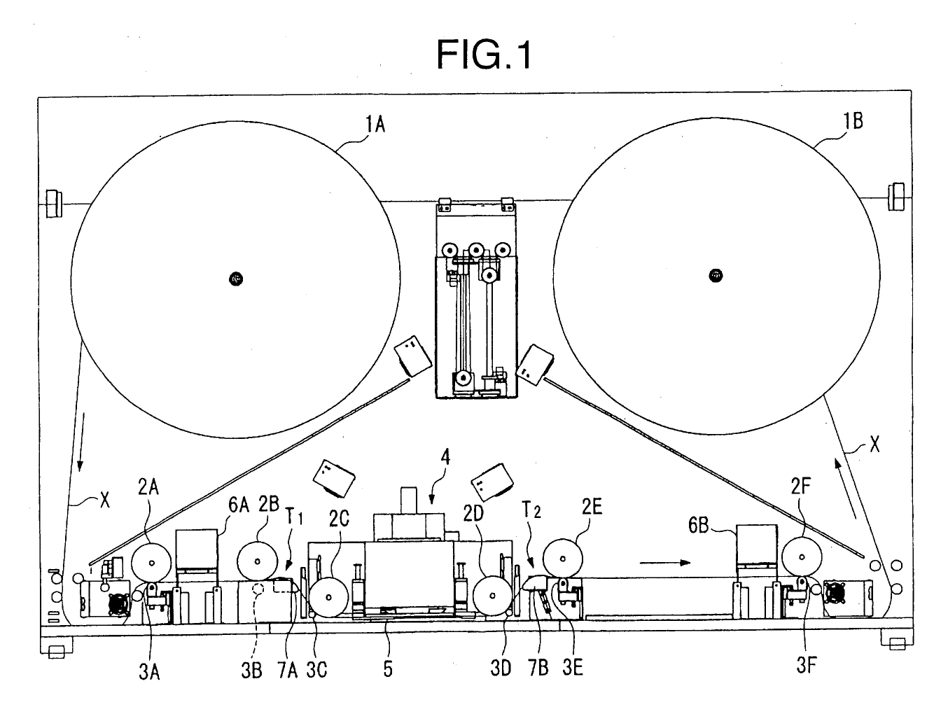

FIG. 1 is a front view showing a traveling system of a handler for TCPs according to an embodiment of the invention. In FIG. 1, depicted by X is a TCP tape, 1A is a supplying reel, 1B is a receiving reel, 2A to 2F are sprockets, 3A to 3F are sprocket guides, 4 is a measuring part, 5 is a probe card, 6A is an inlet side sensor, 6B is an outlet side sensor, 7A, 7B are flexure formation members and T1, T2 are flexure parts. Of the sprockets 2A to 2F, depicted by 2B is a supplying side sprocket, 2C is an inlet side sprocket, 2D is an outlet side sprocket, and 2E is an receiving side sprocket.

The TCP tape X is wound around the supplying reel 1A before testing the TCP tape X, and the TCP tape X is sequentially unwound from the supplying reel 1A by the rotation of the sprockets 2A to 2F and is transferred to the measuring part 4 where each TCP 10 is tested, then it is sequentially rewound around the receiving reel 1B after each TCP 10 is tested by the measuring part 4. The receiving reel 1B rewinds thereon the TCP tape X tested by the measuring part 4. The sprockets 2A to 2F are controlled so as to be rotated in synchronization with each other by a controller, not shown, whereby the TCP tape X is sequentially intermittently traveled from the supplying reel 1A toward the receiving reel 1B.

Of the respective sprockets 2A to 2F, the sprocket 2 is provided at the position closest to the supplying reel 1A, the sprocket 2B is provided at the inlet side relative to the measuring part 4 when viewed from a traveling direction of the TCP tape X (the supplying reel 1A→the receiving reel 1B). Further, the sprockets 2C and 2D constitute a part of the measuring part 4, wherein the inlet side sprocket 2C is provided at the inlet side of the TCP tape X while the outlet side sprockets 2D is provided at the outlet side of the TCP tape X. Further, the receiving side sprocket 2E is provided at the outlet side relative to the measuring part 4 while the sprockets 2F is provided at the position closest to the receiving reel 1B.

The sprockets 3A to 3F are provided to correspond to the sprockets 2A to 2F for allowing the TCP tape X to contact the corresponding sprockets 2A to 2F with pressure.

The measuring part 4 is configured to move up and down and sequentially depresses each TCP 10 provided on the TCP tape X which is intermittently traveled toward the probe card 5 provided under the TCP tape X. That is, the measuring part 4 is lowered every time the TCP tape X is intermittently stopped to allow the test pads 10b of each TCP 10 which is positioned immediately over the probe card 5 to contact each pin provided on the probe card 5 to be connected thereto. At this time, each TCP 10 is moved up and down while it is supported by the sprockets 2C and 2D at the front and the back thereof. The probe card 5 is connected to a semiconductor integrated circuit tester, wherein an operation of each TCP 10 which is allowed to contact the probe card 5 to be connected thereto at the measuring part 4 is tested by the semiconductor integrated circuit tester. FIG. 1 shows a sate where the measuring part 4 is lowered.

An inlet side sensor 6A is provided on the traveling route of the TCP tape X between the sprocket 2A and the supplying side sprocket 2B for detecting the presence of the IC chip 10c on each TCP 10 before the IC chip 10c is tested. Only the TCP 10 having the IC chip 10c presence of which is detected by the inlet side sensor 6A is depressed toward the probe card 5 by the measuring part 4. Further, the outlet side sensor 6B is proved on the traveling route of the TCP tape X between the receiving side sprocket 2E and the sprocket 2F for detecting the presence of the IC chip 10c on each TCP 10 after the TCP 10 was tested. A punch unit, not shown, is provided between the outlet side sensor 6B and the receiving side sprocket 2E, and each TCP 10 having such a defective IC chip 10c is, for example, removed from the TCP tape X by the punch unit. The outlet side sensor 6B is provided for detecting whether the TCP 10 having such a defective IC chip 10c is properly removed or not by the punch unit.

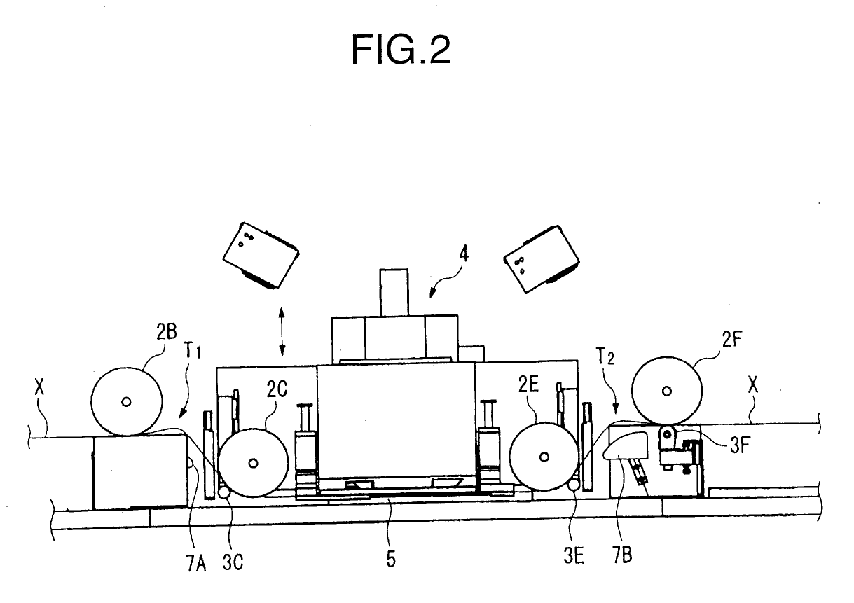

The flexure formation member 7A of the flexure formation members 7A, 7B is provided on the traveling route between the supplying side sprocket 2B and the inlet side sprocket 2C while the flexure formation member 7B of the flexure formation members 7A, 7B is provided on the traveling route between the outlet side sprocket 2D and the receiving side sprocket 2E. The flexure formation members 7A, 7B are provided, as shown in FIG. 2, so as to move toward or away from the TCP tape X for forming the flexure parts T1, T2 in the TCP tape X. That is, when the TCP tape X is rewound by the receiving reel 1B and stretched between the supplying reel 1A and receiving reel 1B in a state where the flexure formation members 7A, 7B are move toward the TCP tape X, the flexure parts T1, T2 are formed on the TCP tape X. FIG. 1 shows that the flexure formation members 7A, 7B are moved toward the TCP tape X.

An operation of the handler for TCPs having the foregoing configuration is described next in detail.

When each TCP 10 is tested by the semiconductor integrated circuit tester, the TCP tape X unwound from the supplying reel 1A then it is passed through, as shown in FIG. 1, the sprocket 2A→the supplying side sprocket 2B→the inlet side sprocket 2C→the outlet side sprocket 2D→the receiving side sprocket 2E→the sprocket 2F, and is rewound by the receiving reel 1B and stretched between the supplying reel 1A and receiving reel 1B.

At that time, when the flexure formation members 7A, 7B are moved toward the TCP tape X, and the flexure formation members 7A, 7B are moved away from the TCP tape X upon completion of the foregoing rewinding and stretching of the TCP tape X, the flexure parts T1, T2 are formed between the front and the back of the measuring part 4 as shown in FIG. 2, namely, between the supplying side sprocket 2B and the inlet side sprocket 2C and between the outlet side sprocket 2D and receiving side sprocket 2E. The flexure parts T1, T2 are maintained while the TCP tape X is sequentially intermittently to test each TCP 10 because the sprockets 2A to 2F are all rotated in synchronization therewith.

That is, since the amount of flexure of the TCP tape X at the flexure parts T1, T2 is set such that the TCP tape X is not pulled toward the longitudinal direction even if the measuring part 4 is moved up and down, the TCP tape X can be traveled without applying surplus tension to the TCP tape X in the longitudinal direction,

Further, as the flexure parts T1, T2 are formed at the front and the back of the measuring part 4, a degree of freedom is generated in the direction of the operation of the measuring part 4. That is, an angle alignment mechanism can be provided on the measuring part 4 by the provision of the flexure parts T1, T2. The angle alignment mechanism is a mechanism to adjust an angle of the TCP 10 (i.e. TCP tape X) relative to and within the opposed face of the probe card 5 so as to establish positioning between the test pads 10b of each TCP 10 and the measuring pins of the probe card 5.

That is, although the angle alignment mechanism is provided at the probe card side according to the conventional handler for TCPs, an angle of each TCP 10 relative to the probe card 5 can be adjusted at the measuring part 4 side without applying tension to the TCP tape X by providing the flexure parts T1, T2 according to the embodiment of the invention. As mentioned above, according to the invention, since the handler for TCPs for sequentially intermittently traveling a TCP tape X comprises a plurality of continuously connected TCPs in a shape of a tape so as to move a measuring part provided in the midway of a traveling route of the TCP tape X in a direction perpendicular to a surface of the TCP tape X for allowing each semiconductor chip on each TCP to sequentially contact an opposed probe card to connect thereto, wherein flexure parts are formed on the TCP tape X forward and backward of the measuring part in the traveling direction of the TCP tape X, and the TCP tape X is traveled by sprockets disposed forward and backward of the flexure parts in the traveling direction of the TCP tape X, that is, since the TCP tape is traveled without applying tension using tension guides which have been conventionally provided at the front and the back of the measuring part, stress to be applied to the TCP tape during the travel thereof can be reduced.

The disclosure of Japanese Patent Application No. 2001-361158 filed Nov. 27, 2001 including specification, claims, and drawings, is incorporated herein by reference.

What is claimed is:

1. A handler for TCPs for sequentially intermittently traveling a TCP tape comprising a plurality of continuously connected TCPs in a shape of a tape so as to move a measuring part provided in the midway of a traveling route of the TCP tape in a direction perpendicular to a surface of the TCP tape for allowing each semiconductor chip on each TCP to sequentially contact an opposed probe card to connect thereto;
wherein flexure parts are formed on the TCP tape forward and backward of the measuring part in the traveling direction of the TCP tape, and the TCP tape is traveled by sprockets disposed forward and backward of the flexure parts in the traveling direction of the TCP tape.

2. The handler for TCPs according to claim 1, further comprising flexure formation members provided at the front and the back of the measuring part, wherein said flexure formation members are freely movable toward or away from the TCP tape.

3. The handler for TCPs according to claim 1, wherein the measuring part has an angular alignment mechanism for adjusting an angle of each TCP relative to and within an opposed face of the probe card.

4. A method of traveling a TCP tapecomprising steps of:
sequentially intermittently traveling a TCP tape comprising a plurality of continuously connected TCPs in a shape of a tape so as to move a measuring part provided in the midway of a traveling route of the TCP tape in a direction perpendicular to a surface of the TCP tape for allowing each semiconductor chip on the TCPs to sequentially contact an opposed a probe card to connect thereto, said method further comprising:
forming flexure parts on the TCP tape forward and backward of the measuring part in the traveling direction of the TCP tape; and
traveling the TCP tape to be traveled by sprockets disposed forward and backward of the flexure parts.

5. The method of traveling a TCP tape according to claim 4, wherein the flexure parts are formed by providing flexure formation members at the front and the back of the measuring part in the traveling direction of the TCP tape, said flexure formation members are freely movable toward and away from the TCP tape.

6. The method of traveling a TCP tape according to claim 4, further comprising adjusting an angle of each TCP in the measuring part relative to and within an opposed face of the probe card.
